(19) United States
(12) Patent Application Publication
(10) Pub. No.: US 2023/0334213 A1
(43) Pub. Date: Oct. 19, 2023

(54) ANALOG/MIXED-SIGNAL DEFECT SIMULATION AND ANALYSIS METHODOLOGY

(71) Applicant: D KEVIN CAMERON, SUNNYVALE, CA (US)

(72) Inventor: D KEVIN CAMERON, SUNNYVALE, CA (US)

(21) Appl. No.: 18/135,732

(22) Filed: Apr. 17, 2023

Related U.S. Application Data
(60) Provisional application No. 63/331,874, filed on Apr. 17, 2022.

(51) Int. Cl. G06F 30/38; G06F 30/367

(52) U.S. Cl. CPC G06F 30/38; G06F 30/367

(57) ABSTRACT

A system, method, and apparatus for analog/mixed-signal defect simulation and analysis methodology. Block-level behavioral models simulated at transistor level, using automated or manual techniques, are binned for all the possible defects that have similar results. A likelihood of a given block-level behavioral model is determined from the likelihood of the defects it represents. Deliberate binning in another embodiment is based on one or more functions of the given block being simulated, e.g., by amplifier gain for an analog amplifier, or by speed/power for a digital part. One or more bins are ‘defect-free behavior’ that cover nominal and corner behavior (power & timing), from manufacturing variability, which may be labeled as “failed” or “degraded” depending on specific performances. For standard parts, test-benches provide the binning from the block-level behavioral models as a result.

### CROSS-REFERENCE TO RELATED APPLICATIONS

This application claims priority to provisional application(s): Ser. No. 63331874, filed Apr. 17, 2022, titled “ANALOG/MIXED-SIGNAL DEFECT SIMULATION AND ANALYSIS METHODOLOGY”, the disclosure of said application is incorporated by reference herein in its entirety.

### FIELD OF TECHNOLOGY

This disclosure relate generally to the technical fields of electronic circuit and system simulation, and in one example embodiment, this disclosure relates to a method, apparatus and system of creating, managing, and testing using block-level behavioral models for electronic circuit and systems using analog/mixed-signals.

### BACKGROUND

Digital circuit fault analysis is a mature area of electronic design analysis (EDA), but analog circuit fault analysis has never been automated to the same level. Part of the problem is the slow speed of analog simulation that is used to verify the effects of circuit defects. In addition, the fact that most defects are small parametric shifts rather than catastrophic damage, makes analyzing every defect in a large design impractical.

### SUMMARY

In one embodiment, the solution to the simulation performance issue is to use block-level behavioral models, but applying device defects to behavioral models is not possible - the defects can only be described at primitive component level (transistors, resistors etc.) - so the behavioral models have to be built in a way that incorporates the defects.

Rather than creating different behavioral models for each defect, the block, for which the block level model is generated, is simulated at transistor level with all the possible defects within time constraints (the “known defects”), and the results compared for each defect. The results for many defects will be quite similar and any recognizably different behavior can be considered a “bin”. A behavioral model can be generated for each bin using automated or manual techniques, and its likelihood determined from the likelihood of the defects it represents. If the function of a block is understood, the binning can be more deliberate, e.g. by amplifier gain for an analog amplifier, or by speed/power for a digital part. One or more bins (due to manufacturing variability) are the defect-free behavior covering nominal and corner behavior (power & timing), some bins may be considered “failed”, and some as just “degraded”. For standard parts, test-benches can be created that provide the binning as a result. In one embodiment, if measuring X factors at Y different levels, this produces X*Y total bins for behavior models and binning options.

For example, if three factors of power, speed, and gain, with two levels each (high and low), then a resultant six total bins results. The number of defect models that run at transistor level is higher, e.g., a dozen possible defects for each transistor device type and more than a dozen transistors per block. In another embodiment, there are a semi-infinite number of parametric defects to consider. Therefore, the binning process reduces the number of possible options for defect behavior /analysis by orders of magnitude, thereby speeding up the simulation process. In one embodiment, a given defective model, e.g., a transistor level single device simulation model is used as a proxy for the bin behavioral model to start with, and then the bin behavioral model can be iteratively developed over time and with data to be more sophisticated to encompass more and different types of different single device simulation models.

This same approach can be used at higher architecture levels as well, for higher-level blocks simulating and binning a multiple lower level blocks’ bin behavioral models. In another embodiment, AI is continuously and dynamically improving models, e.g., learning and training or reconfiguration, over time while the simulations are running (in parallel) for a given defect analysis. This can also account for transient conditions and new factors. If a defect analysis does not notice a particular defect, the circuit is modified to improve coverage, but is not appearing in test results. For example, if a necessary component is removed from a circuit, and the test results do not change, then the test is not sufficiently comprehensive. Extra circuitry is added to improve coverage in yet another embodiment, and the test process is restarted for the relevant block.

The methods, operations, processes, systems, and apparatuses disclosed herein may be implemented in any means for achieving various aspects, and may be executed in a form of a machine-readable medium, and/or a machine accessible medium, embodying a set of instructions that, when executed by a machine or a data processing system (e.g., a computer system), in one or more different sequences, cause the machine to perform any of the operations disclosed herein. Other features will be apparent from the accompanying drawings and from the detailed description that follows. Accordingly, the specification and drawings are to be regarded in an illustrative rather than a restrictive sense. The present invention is defined by the features of the appended claims.

This Summary is provided to introduce a selection of concepts in a simplified form that are further described below in the Detailed Description. This Summary is not intended to identify key or essential features of the claimed subject matter, nor is it intended to be used as an aid in determining the scope of the claimed subject matter.

### BRIEF DESCRIPTION OF THE VIEW OF DRAWINGS

Example embodiments are described by way of illustrations and are not limited by the figures of the accompanying drawings, wherein:

FIG. 1 is a flow diagram for analyzing a circuit component/block using binning and model generation, according to one or more embodiments.

FIG. 2 is a behavior model diagram that uses models generated from the flow diagram, according to one or more embodiments.

FIG. 3 is a feedback system using least-mean-squares (LMS) algorithm for matching a plant emulator (bin behavioral model) to a plant (behavioral defect), according to one or more embodiments.

FIG. 4, a representation of a computing device, according to one or more embodiments.

FIG. 5 is a flowchart of a method of using bins to characterize behavior, generation of behavioral models to match bins, and use of representative model with bin weighting, according to one or more embodiments.

The drawings referred to in this description should be understood as not being drawn to scale, except if specifically noted, in order to show more clearly the details of the present disclosure. Same reference numbers in the drawings indicate like elements throughout the several views. Other features and advantages of the present disclosure will be apparent from accompanying drawings and from the detailed description that follows.

### DETAILED DESCRIPTION

A method, apparatus and system for analog/mixed-signal defect simulation and analysis methodology using block-level behavioral models simulated at transistor level, using automated or manual techniques, are binned for all the possible defects that have similar results is disclosed. In the following description, for the purposes of explanation, numerous specific details are set forth in order to provide a thorough understanding of the various embodiments. It will be evident, however to one skilled in the art that various embodiments may be practiced without these specific details.

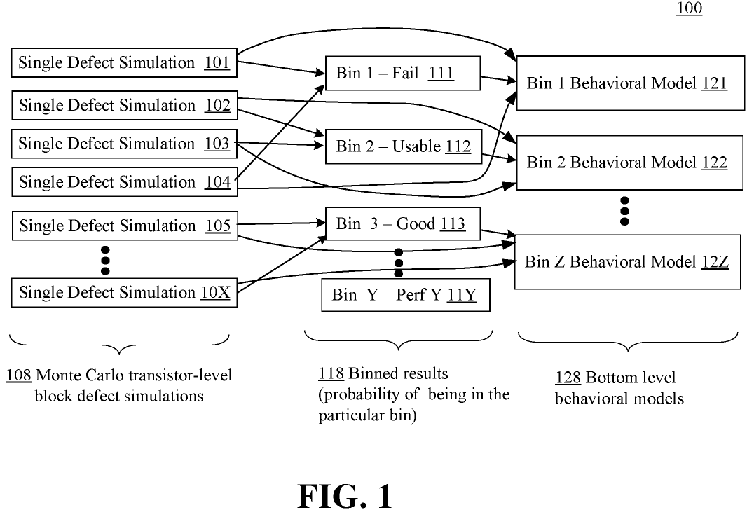

Referring to FIG. 1, a flow diagram 100 is shown for analyzing a circuit component/block using binning and model generation, according to one or more embodiments. For digital circuits, embodiments of a NAND gate, a flip-flop, or the like are used for the process. For analog circuits or devices, a comparator, or the like, is used for the process. Since the circuit is small, all known defects can be applied and Monte Carlo simulations used if there is variability in the silicon process.

Flow diagram 100 illustrates exemplary single defect simulations 101, 102, 103, 104, 105 and though 10X, where ‘X’ is any quantity of defect simulations desired; categorized as 108 Monte Carlo transistor-level block defect simulations. Different bins for categorizing the behavior from the defect simulations include Bin 1 for fail behavior 111, bin 2 for usable behavior 112, bin 3 for good behavior 113 (between behavior of fail and usable), and bin Y for behavior Y 11Y, where Y is any quantity of bin characterization desired. Said bins are categorized as 118 binned results (probability of being in the particular bin). Lastly, bottom level behavioral models 128 are shown as bin 1 behavioral model 121, bin 2 behavioral model 122, and bin Z behavioral model 12Z, where Z is any quantity of behavioral models desired.

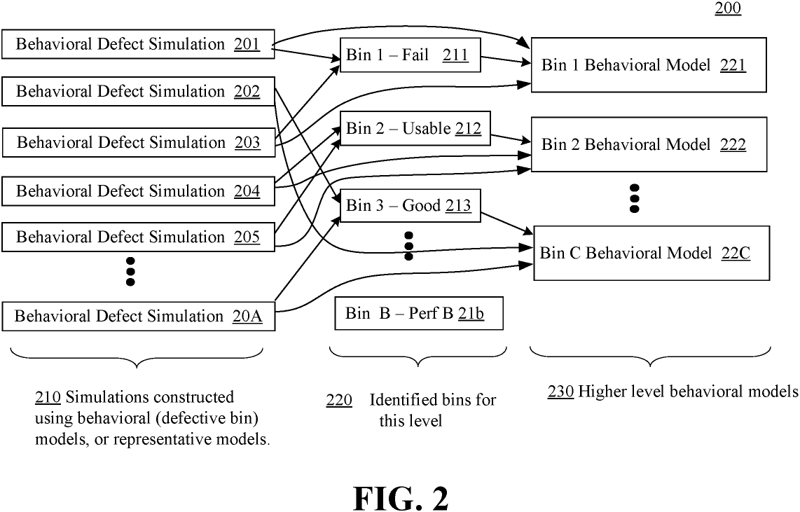

Referring to FIG. 2, a behavior model diagram 200 is shown that uses models generated from the flow diagram, according to one or more embodiments. Diagram 200 repeats the process at the next level of design using the models generated in FIG. 1 to determine the behavior. If the single defect simulation is fast enough or the behavioral model cannot be generated, a representative single-defect (e.g., transistor level) model can be used with the bin weighting rather than using a behavioral model for the next level.

Diagram 200 illustrates simulations constructed using behavioral (defective bin) models, or representative models 210, with exemplary behavioral defect simulations 201, 202, 203, 204, 205 and though 20A, where ‘A’ is any quantity of defect simulations desired. Different bins for categorizing the behavior from the behavioral defect simulations include bin 1 for fail behavior 211, bin 2 for usable behavior 212, bin 3 for good behavior 213 (between behavior of fail and usable), and bin B for behavior B 21B where B is any quantity of behavioral models desired. Said bins are categorized as 220 Identified bins for this level). Lastly, higher-level behavioral models 230 are shown as bin 1 behavioral model 221, bin 2 behavioral model 222, through bin C behavioral model 22C, where C is any desired quantity of bins.

To determine full-chip or higher level block behavior, start by simulating with the behavioral models using the defect-free bin models to determine the good behavior, and then re-simulate with defective bin models to see if the degradation in behavior is noticeable. In some cases (like that of the amplifier), it may be possible to determine which bins will cause design failure without simulation because some parameter (like gain, speed, power consumption) is too low in that bin.

Multiple degraded bin models may be used at the same time if that reflects the defect behavior of the silicon, noting that models correspond to a particular area of silicon and some (transient) defects (like radiation) may require moving a group of models to use a different bin. For example, for a soft error from radiation effect flipping a bit, the process would switch to the model for transient effects, e.g., use of the defect model lasts until the ionization dissipates. So if the transient defect behaves like a short, then the simulation model for that short is used temporarily. Models representing failures, like a latch-up, can be annotated with recovery methodology (e.g. power cycling) so recovery can be attempted if that particular failure is recognized.

### Modeling by Observation

Bernard Widrow describes a technique for modeling complicated/non-linear systems with neural networks using his least-mean-squares algorithm. For more information, see: “Adaptive Inverse Control: A Signal Processing Approach, Reissue Edition”, Bernard Widrow, Eugene Walach, ISBN: 978-0-470-23160-9, February 2008, Wiley-IEEE Press, which is incorporated herein by reference. That technique can be used to copy the behavior of transistor level circuit simulations (SPICE) to event-driven block level behavior (neural nets), and artificial intelligence (AI) accelerator hardware can run the generated models. For digital circuits automatic test pattern generation (ATPG) can be used to create the input for the tuning process. As with looping through a simulation trying different defects (see below) the simulator can loop over the ATPG until the fast model is tuned. The fast model may be a mix of modeling, e.g. fast RTL (Verilog) with input and output being tunable, so that the minimum amount of guesswork and estimation is required.

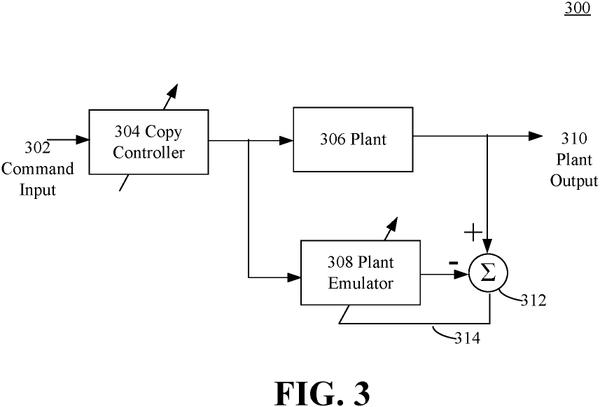

Referring now to FIG. 3, a feedback system is shown using a least-mean-squares (LMS) algorithm for matching a plant emulator to a plant, according to one or more embodiments. This model is an example of digital twinning based on gradient descent optimization (an analog technique), e.g., using LMS algorithm based on Bernard Widrow’s modeling technique referenced above. This provides a feedback system that measures the difference between an output of the plant 306, and the plant emulator 308 to obtain an LMS error that is fed back into adjusting plant emulator 308 to reduce the error as close to zero as possible. In another embodiment for digital twinning, a digital solution uses a mix of genetic algorithm combined with a symbolic simulation as and SAT solvers. Simple combinational logic can be treated as an analog function, since it has no hidden state. Storage elements can be identified independently and modeled manually if not handled by the AI approach described herein.

Applying FIG. 3 to FIG. 1 in one embodiment, plant 306 is, in one embodiment, single defect simulations 101 and 104 that create a common behavior to has been characterized as Bin 1 (Fail) 111, and plant emulator 308 is Bin 1 Behavioral Model 121, which starts with simple default of single defect simulation 101 and is then iterated over time and with additional data to be a more comprehensive behavior model, e.g., that includes more features such as single defect 104. That is, while the behavioral model for 121 is being constructed, either the 101 or 104 single defect models can be used instead temporarily in its place. Behavioral model 121 can be utilized in a next higher architectural level, e.g., FIG. 2, with other models, e.g., to form behavioral defect simulation 201 in FIG. 2. This is a quick way to start simulation with one of the actual defect models, while an improved behavioral model is being developed.

Applying FIG. 3 to FIG. 2 in one embodiment, plant 306 is behavioral defect simulations 201 and 203 create a common behavior been characterized as bin 1 (Fail) 211, and plant emulator 308 is bin 1 behavioral model 221. Initially, bin 1 behavioral model 221 can start with a simple default premise of using one of the behavior defect simulations, e.g., 201. This default premise can be iterated over time and with additional data to be a more comprehensive behavior model that includes more features of behavioral defect simulation 203, etc. if and as they arise. Behavior defect simulation 201 itself includes lower level behavioral models, e.g., bin 1 behavioral defect simulation 121 from FIG. 1 that is fed into the higher architecture level used in FIG. 2.

In normal running, the simulator may run both fast and slow models for a block (with the same inputs), passing on the fast model results as early as possible, and the slow model to verify what was communicated. In the event of a (serious) mismatch, the simulator would attempt to back up in time and just use the slow model results, and may revert to a model-tuning mode for the fast model. The automatic behavioral modeling would be used to model the inputs of the following stages to create “stubs” (e.g., just gate capacitance) for the slow model outputs to get correct loading (see wiring/parasitic modeling below).

### Non-Simulation Analysis

Circuit analysis may reveal some defects to be equivalent; this is known as defect collapsing. For example, a number of resistors in series will exhibit the same behavior for any one missing (open) resistor or the whole chain has an unacceptably high resistance. Those defects then map to the same bin model.

### Aging

Continual use/abuse (overuse) of some components will cause failure with time, that can be handled by transitioning from one bin to another, i.e. rather than incorporating aging directly into the model, some measure of activity can be used to trigger the simulator to switch to a different bin model - noting that there might be several transitions before a bin causing system failure is selected.

Aging of an entire chip can be accelerated in simulation by shortening the time to degradation in the algorithms, and/or telling the models they are at some far future time. For example, a flash memory cell fails after a few thousand writes. At that time of failure, the model would be switched to a failure model for aging, which allows for testing of wear leveling.

### Scripting

Most traditional simulators have a simple three-phase approach - read the design, elaborate, start simulating. The simulation is usually controlled by a single-threaded top-level script unique to the simulator in question or some programming language like Tc1 or Python.

A defect simulator is different in that it is desirable to de-elaborate/re-elaborate (subtract/ add) pieces, e.g., sub-circuits and wiring, as you go, and be able to go back in time and rerun things, e.g., rerun just the simulation (and avoid restarting the entire simulation from scratch). For example, one methodology starts with all the ‘open’ hard defects that essentially drops each component in turn and returns to the simulation to determine if simulation can detect the missing components as a baseline to test. Following that, ‘short’ defects would be tested with the tests that detected opens. Afterwards, ‘parametric’ defects would be tried with the known good tests. For defects not detected, new tests would be added and/or detection circuitry. With circuits including error correction, multiple defects may need to be applied for a test to show a failure. In this case, more than one defective bin model may be used in a test simulation. If a large design is simulated, then there may be different defect behaviors needed in different blocks, and it is desirable to attach scripts to the blocks and have them running in parallel (see Aging above). Scripts for running the behavioral defect models can be attached to the design intellectual property (IP) and made available to downstream users who may not have access to the transistor level IP. In an object-oriented environment, the scripts/programs attached to an IP block would be exposed through an opaque application programming interface (API) belonging to the particular IP. This would give users the option to run a simulation with failing models.

Adding scripting to existing simulators allows additional functionality to be implemented outside the normal flow of simulation, e.g. check-point/restart, which can be added using an OS feature like “fork”, which lets any simulator cycle over a section of simulation doing different things each time (model tuning or defect injection). The “fork” approach can also be used to redo elaboration of a particular component when switching between models in the simulator that are not capable of doing that otherwise.

### Back-Annotation/DFX

The process of applying defects is similar to that of back-annotation - adding the effects of wiring and parasitics into the design from layout extraction or wiring load guesswork. As with defects, it may be desirable to add and remove back-annotation while simulating. In particular if a circuit is being synthesized and needs to try different layouts, having the synthesizer ability to talk interactively with the simulator enables quick feedback on defect sensitivity and performance, allowing optimization for yield, e.g., design for yield (DFY). These goals apply to a design for excellence (DFX).

Back-annotated components may be pre-processed into binned behavioral models the same way design-intent components are, thus allowing wiring defects to be handled with the same methodology.

### Process Alignment

For yield and escape calculations information is required from the manufacturing processes about the likelihood of each possible defect. Defect/fault coverage is initially used to evaluate the quality of the tests that can be run in simulation, and then for the tests that will be run on test equipment in manufacturing. Yield calculations should correlate with binning results from part testing, whereas escape calculations will be derived from the yield numbers and/or the observed failure rates.

Failing ICs can be subjected to deeper testing to analyze which components within the chip have failed. With fast behavioral modeling and a history of failure modes (from coverage simulation), it is possible to suggest a minimum set of failing/degraded models that could cause the observed faults, and given a likely behavioral model the actual set of possible defects can be tried to see if a particular defect is identified. Aggregated results of such analysis would indicate if particular problems with the process are causing faults, or that manufacturing equipment is faulty.

### System Testing

The behavioral defect modeling of ICs can be reused in board and system level simulation to determine the reliability of a full system, which is often required by safety standards like ISO26262, and aircraft worthiness. As with lower level behavior, sub-systems can be characterized by binning. The binning process can be applied to mechanical system models in the same way as electronics.

### Anomaly Detection

A simulation of a system is run in parallel with the real system, in one embodiment, to detect departure from normal behavior, and attempt to match it by trying different degraded/failed models to get a best fit. Continual refinement through the modeling stack (see checkerboard testing), may be able to pinpoint likely candidates for the root cause.

For example, if an autonomous vehicle is pulling to the left while driving, the digital twin can be evaluated for what likely causes would result in that behavior by substituting defect models into the simulation of the defect-free model.

### Self-Simulation

Anomaly detection may be run within the system itself, so that the system can avoid unexpected catastrophic failure. In larger systems like ships, that carry spare parts, the self-simulation would make maintenance recommendations. If spares are not available, the simulator can experiment with other forms of repair and make suggestions (ahead of the action being required).

For example, for a semiconductor fab facility, self-simulation can correlate a defect in the electronic circuits to a machine likely to exhibit that behavior in the circuit, e.g., circuit gain might be correlated to a mask layer being misaligned, and that in turn might arise from a particular reticle operation.

### Transient Defects

In situations where the defect is transient (e.g. radiation causing ionization), a degraded bin may be selected for use for a limited period.

### Simulator Internal Methodology

A secondary problem with analog simulation is that the simulators are not very interactive or scriptable. Because the block-level models are behavioral and can be mostly event-driven, it is easier to switch between them at runtime. When a test is found with a failing bin model, the simulator can be made to cycle back over a section of the test trying the other (degraded) bins to see what the overall impact of defects is. E.g. when testing digital, that would mean using the equivalent of a stuck-at defect to identify a usable test, then reusing the test with the degraded bin models to determine which timing bin the final part will end up in.

A circuit state from a (fast) simulator can be used as the initial state for an accurate (analog) simulation; a fast simulation run can “spawn” accurate simulations as it goes. E.g. in a simulation of a computer running software, particular sequences that trigger behavior (e.g. a cache miss) can be rerun as a sub-process replacing the fast models with slower more accurate/informative models).

Switching between models is essentially the same as removing one and inserting another. Models in simulation interact with “nodes” in the simulator through “drivers” and “receivers”. When detaching a model, its drivers and receivers are either deleted, marked inactive or just have zero drive strength. Unlike normal simulation (in Verilog-AMS/SystemVerilog/VHDL) the structure of “signal resolution” is handled dynamically in the defect simulator, an example process is:
1. Convert drivers losslessly to a common (resolvable) level.
2. Resolve drivers to get the value being driven.
3. Communicate resolved value to receivers (can be lossy).

When switching between an all-digital simulation and, for example a back-annotated simulation, the common level will change from being digital (1s and 0s) to analog (Voltage and current). If all receivers have lossy conversions some optimization may be possible, in particular the resolver structure can be viewed as a circuit itself, and the AI optimization techniques for modeling blocks applied to it.

### Coverage Database

Because defect simulation requires running lots of simulations or static analysis tools in parallel, a common database is needed through which the tools can interact. Once circuit simulations are up and running they will query the database for work to be done, rather than stopping and being relaunched (see checkerboard testing below).

Traditional SPICE simulators tend to be batch-oriented, using files for input and output, which is extremely inefficient with large designs. For backward compatibility, file systems can be created virtually using software like Fuse2, which can create file system objects that map to other things (like archives and databases).

Particular blocks in a design may be more sensitive to certain defects, and that information can be carried in the database to aid DFX. It would be there for transistor level defect analysis, but block level models would carry merged data. E.g. if a block has no metal-2 tracks it is maybe insensitive to defects in that layer and can be marked up as such. Likewise, a large transistor (mostly FinFET fingers) will be more sensitive to gate/source/drain level defects than a standard cell, which is only ~ 30% transistor.

DFY data may also be carried with the block level models in the database, and may be populated from system testing (see above) with tester results, i.e. the fab data for defect modeling is used with data mining of test results to align the DFX data with reality. Test programs may be tuned in the direction needed to maximize that information (rather than purely functional test).

The database can be part of the simulator, distributed across multiple simulators and/or standalone. If part of a simulator, it may be saved as a standalone database for later use. A common database for EDA work is OpenAccess, the simulator(s) may pretend to be an OpenAccess database, which avoids having to copy data to and from an external database. That can also be viewed as having a database that is capable of doing simulation itself.

### Fault Probability

Because this approach uses approximate modeling, and because of manufacturing variability, the fault coverage results have limited accuracy. In aggregate, the results should match reality, but individual tests will only have a probability of being correct. When logging a test/binning result a probability for the reliability of the value is added. In initial testing low probability coverage is better than no coverage because the no-coverage areas are the ones that require tests to be created.

Low-grade fast simulators and static analysis tools may be used to do initial population of the database, e.g. with simple stuck-at fault testing for digital, the results would have low probability of being correct for all bins. As time allows, higher quality simulations can be used to fill in better data.

For testing with RF chips, specialist simulators that use techniques like spectral modeling maybe used with the degraded bins, for determining behavior like PLL locking accurately.

### Checkerboard Testing

Given the basic coverage data, a simulator can choose to use the fastest (least accurate) models in areas of a design known not to be covered by a particular test. In languages like C/C++ used for simulator code, swapping between models can be performed quickly by just pointing the simulator at different code that uses the same simulation data. That avoids having to do any replumbing of connections. Updating of C++ object virtual-function tables is an atomic operation that achieves that (see wandering-threads).

In one embodiment, test models are dynamically switched during simulation without restarting or losing results to that point in the test. For example, a simulator can start by running a test with a defect-free model, then swap in one or more defect models and repeat a relevant portion of the simulation without restarting the whole simulation. That is, the simulation just loops around a particular piece of defective model test by just running through a desired defect model(s) for a particular transistor in question.

In another embodiment, a standard code interface is used for the defect model regardless of whether the defect model is good or bad (simulator data structure does not change when the defect model code is changed). Thus, different defect models can be cycled through the simulator to identify whether the behavior changes or just to improve performance, e.g., speed of simulation. For example, optimal transistor models can be used for the instances, replacing variables with constants when compiling the model. For example, a precompiled device model, e.g., a SPICE model can have hundreds of different parameters, but this can be reduced to just a few or to none (model is unique to a transistor), for different instances. Per-instance defect models can also be cached in a library for repeated future use.

### I. Exemplary Summary Concepts

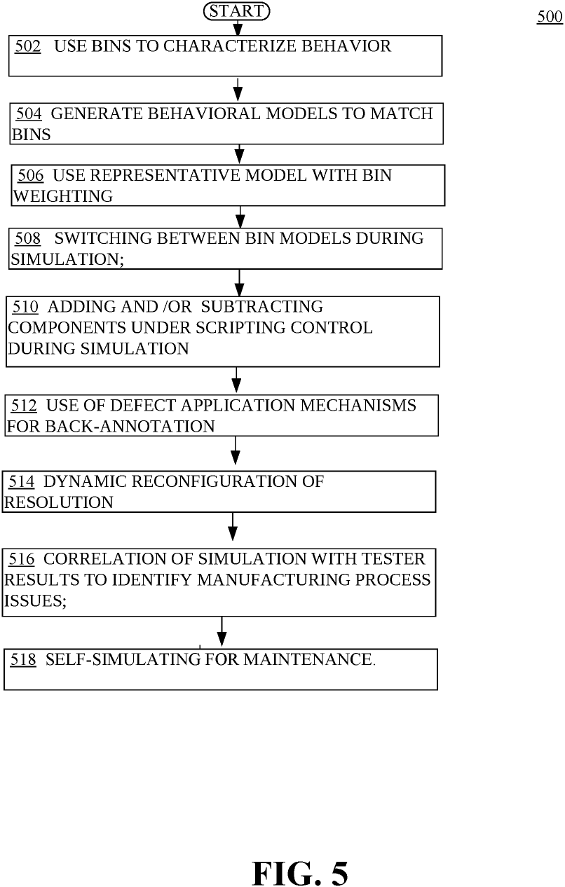

It is noted that the foregoing description has presented at least the following concepts: Concept 1. A method, system, or a computer-readable medium for storing a set of instructions that when executed cause a computer system to perform the method, comprising at least one of the following operations: noted in flowchart 500 of FIG. 5:
1. Use of bins to characterize behavior 502.
2. Generation of behavioral models to match bins 504.
3. Use of representative model with bin weighting 506.
4. Switching between bin models during simulation 508.
5. Addition and subtraction of components under scripting control during simulation 510.
6. Use of defect application mechanisms for back-annotation 512.
7. Dynamic reconfiguration of resolution 514.
8. Correlation of simulation with tester results to identify manufacturing process issues 516.
9. Use of self-simulation for maintenance 518.

### COMPUTER SYSTEM

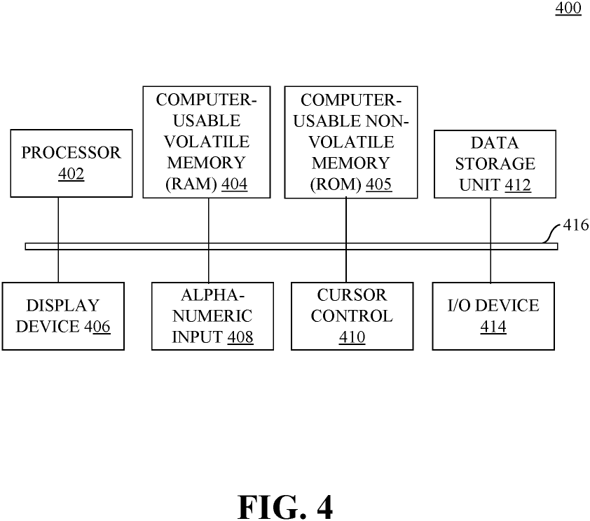

Referring now to FIG. 4, a representation of a computing device 400 is shown, according to one or more embodiments. Exemplary computing device 400 includes components and functionality that are capable of executing instructions to accomplish the functions and operations described herein. Computing device 400 includes components such as a processor 402 coupled to a memory 404, 405, and/or 412. In particular, processor 402 can be a single or multi-processor core, for processing data and instructions. Memory 404, 405, and/or 412 are used for storing and providing information, data, and instructions, including in particular computer usable volatile memory 404, e.g. random access memory (RAM), and/or computer usable non-volatile memory 405, e.g. read only memory (ROM), and/or a data storage 412, e.g., flash memory, or magnetic or optical disk or drive. Computing device 400 also includes optional inputs, such as an alphanumeric input device 408,e.g., a keyboard or touch screen with alphanumeric, function keys, object driven menus; a keypad button, a microphone with voice recognition software running on a processor, or any device allowing a player to respond to an input; or an optional cursor control device 410, e.g., a roller ball, trackball, mouse, etc., for communicating user input information and command selections to processor 402; or an optional display device 406 coupled to bus for displaying information; and an optional input/output (I/O) device 414 for coupling system with external entities, such as a modem for enabling wired or wireless communications between system and an external network such as the Internet, a local area network (LAN), wide area network (WAN), virtual private network (VPN), etc. Coupling medium 416 of components can be any medium that communicates information, e.g., wired or wireless connections, electrical or optical, parallel or serial bus, etc.

The computing device is only one example of a suitable computing environment and is not intended to suggest any limitation as to the scope of use or functionality of the present technology. Neither should the computing environment be interpreted as having any dependency or requirement relating to any one or combination of components illustrated in the exemplary computing system. The present technology may be described in the general context of computer-executable instructions, such as program modules, being executed by a computer. Generally, program modules include routines, programs, objects, components, data structures, etc., that perform particular tasks or implement particular abstract data types. The present technology may also be practiced in distributed computing environments where tasks are performed by remote processing devices that are linked through a communications network. In a distributed computing environment, program modules may be located in both local and remote computer-storage media including memory-storage devices.

### Applications

Still referring now to FIG. 4, flowchart 400 is shown of a process for analog/mixed-signal defect simulation and analysis methodology. The process includes generation, management, and analysis of block-level behavioral models simulated at transistor level, using automated or manual techniques that are binned for all the possible defects that have similar results. In another operation, a likelihood of a given block-level behavioral model is determined from the likelihood of the defects it represents. A subsequent operation deliberately bins block-level behavioral models based on one or more functions of the given block being simulated, e.g., by amplifier gain for an analog amplifier, or by speed/power for a digital part. One or more bins are ‘defect-free behavior’ that cover nominal and corner behavior (power & timing), from manufacturing variability, which may be labeled as “failed” or “degraded” depending on specific performances. For standard parts, test-benches provide the binning from the block-level behavioral models as a result. In one embodiment, process is carried out, at least in part, by processors and electrical user interface controls under the control of computer readable and computer executable instructions stored on a computer-usable storage medium.

The computer readable and computer executable instructions reside, for example, in data storage features such as computer usable volatile and non-volatile memory and are non-transitory. However, the non-transitory computer readable and computer executable instructions may reside in any type of computer-usable storage medium. In one embodiment, process is performed by the devices, components, and illustrations in FIGS. 1-2.

### Alternatives

The above advantages are exemplary, and these or other advantages may be achieved by the disclosure. Further, the skilled person will appreciate that not all advantages stated above are necessarily achieved by embodiments described herein.

In the foregoing specification, the disclosure has been described with reference to specific example embodiments. It will be evident, however, that various modifications and changes may be made therein without departing from the broader spirit and scope of the invention as set forth in the appended claims.

The connections as discussed herein may be any type of connection suitable to transfer signals from or to the respective nodes, units or devices, for example via intermediate devices. Accordingly, unless implied or stated otherwise, the connections may for example be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice versa. In addition, plurality of connections may be replaced with a single connection that transfers multiple signals serially or in a time-multiplexed manner. Likewise, single connections carrying multiple signals may be separated out into various different connections carrying subsets of these signals. Therefore, many options exist for transferring signals.

Each signal described herein may be designed as positive or negative logic. In the case of a negative logic signal, the signal is active low where the logically true state corresponds to a logic level zero. In the case of a positive logic signal, the signal is active high where the logically true state corresponds to a logic level one. Note that any of the signals described herein can be designed as either negative or positive logic signals. Therefore, in alternate embodiments, those signals described as positive logic signals may be implemented as negative logic signals, and those signals described as negative logic signals may be implemented as positive logic signals.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures can be implemented which achieve the same functionality.

Any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermediate components. Likewise, any two components so associated can also be viewed as being “operably connected,” or “operably coupled,” to each other to achieve the desired functionality.

Furthermore, those skilled in the art will recognize that boundaries between the above-described operations are merely illustrative. The multiple operations may be combined into a single operation, a single operation may be distributed in additional operations and operations may be executed at least partially overlapping in time. Moreover, alternative embodiments may include multiple instances of a particular operation, and the order/sequence of operations may be altered in various other embodiments. Thus, one or more additional new operations may be inserted within the existing operations or one or more operations may be abbreviated or eliminated, according to a given application.

Also for example, in one embodiment, the illustrated examples may be implemented as circuitry located on a single integrated circuit or within a same device. Alternatively, the examples may be implemented as any number of separate integrated circuits or separate devices interconnected with each other in a suitable manner, such as components packaged together in a module, or as components on board or a card. For example, processing in relation to different groups of profiles may be allocated to respective different integrated circuits.

Additionally, the examples, or portions thereof, may implemented as soft or code representations of physical circuitry or of logical representations convertible into physical circuitry, such as in a hardware description language of any appropriate type.

Also, the invention is not limited to physical devices or units implemented in non-programmable hardware but can also be applied in programmable devices or units able to perform the desired device functions by operating in accordance with suitable program code, for example a Field Programmable Gate Array (FPGA).

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as “one, or more than one.” Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are arbitrarily used to distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

As used throughout this application, the word “may” or “can” is used in a permissive sense (i.e., meaning having the potential or ability to do something), rather than the mandatory sense (i.e., meaning must). Similarly, the words “include,” “including,” and “includes” mean “including, but not limited to” the listed item(s).

Various units, circuits, or other components may be described as “configured to” perform a task or tasks. In such contexts, “configured to” is a broad recitation of structure generally meaning “having circuitry that” performs the task or tasks during operation. As such, the unit/circuit/component can be configured to perform the task even when the unit/circuit/component is not currently on. In general, the circuitry that forms the structure corresponding to “configured to” may include hardware circuits. Similarly, various units/circuits/components may be described as performing a task or tasks, for convenience in the description. Such descriptions should be interpreted as including the phrase “configured to.” Reciting a unit/circuit/component that is configured to perform one or more tasks is expressly intended not to invoke 35 U.S.C. § 112, paragraph six, interpretation for that unit/circuit/component.

Unless specifically stated otherwise as apparent from the foregoing discussions, it is appreciated that throughout the present description of embodiments, discussions utilizing terms such as “generating,” “transmitting”, “operating,” “receiving,” “aligning,”, “scaling,” “communicating,” “executing,” “replacing,” or the like, refer to the actions and processes of an integrated circuit, an ASIC, a memory device, a computer system, or similar electronic computing device. The memory device or similar electronic computing device manipulates and transforms data represented as physical (electronic) quantities within the devices’ registers and memories into other data similarly represented as physical quantities within the devices’ memories or registers or other such information storage, transmission, or display devices.

I/We claim:

1. A method of defect simulation testing and analysis for an electronic circuit or system, the method comprising:
simulating a given block of the electronic circuit or system using a plurality of test models;
segregating (characterizing) a plurality of resultant behaviors of the given block into a discrete quantity of behavior-bins that have recognizably different behaviors from each other; and
generating a behavioral-bin model by digital twinning each of the behavioral-bins.

2. The method of claim 1 wherein:
the test models include a defect-free model, one or more of a transistor level model with one or more defects, and a bin behavioral model of one or more levels of blocks.

3. The method of claim 1 wherein:
the operation of digital twinning the behavioral-bin model is performed by either
i) a gradient descent least means squared (LMS) algorithm using a neural network; or
ii) manually creating a model and modifying parameters.

4. The method of claim 1 further comprising:
generating a block-level behavioral model for the given block, that incorporates all known defects for a given bin.

5. The method of claim 1 further comprising:
creating at least one behavior-bin for a defect-free behavior; and
at least one behavior-bin is for failed or sub-optimal electronic circuits or systems.

6. The method of claim 1 further comprising:
switching between the test models during simulation without restarting or losing results to that point in the simulation.

7. The method of claim 1 further comprising:
determining a likelihood for a given block-level behavior-bin model based on an aggregate of a likelihood for each of one or more defects occurring in the respective behavior-bin.

8. The method of claim 1 further comprising:
simulating a higher-level block behavior in the electronic circuit or system by concurrently simulating a plurality of component blocks disposed in the higher-level block.

9. The method of claim 1 further comprising:
determining which behavior-bin will cause design failure without simulation based on a parameter that is below specification.

10. The method of claim 1 further comprising:
operating more than one defect block-level behavioral-bin models concurrently to represent a given defect behavior of the block.

11. The method of claim 1 further comprising:
switching at least one block-level behavioral-bin models in a group to use a different bin in order to simulate a special defect that includes at least one of a transient defect,
an overuse of one or more components, or an aging condition.

12. The method of claim 1 further comprising:
simulating a higher-level block behavior in the electronic circuit or system by using a representative defect model with a weighting representing a whole bin.

13. The method of claim 1 further comprising:
operating a fast model and a slow model simultaneously for a given block;
communicating results from the fast model when available;
verifying the results of the fast model based against results from the slow model; and
replacing the results from the fast model, if the results of the fast model do not match the results of the slow model, with either the results only from the slow model or reverting to a model-tuning mode.

14. The method of claim 1 further comprising:
attaching to and running in parallel one or more script for an existing simulator of at least one block in the electronic circuit or system currently-being simulated;.

15. The method of claim 1 further comprising:
communicating between a simulator and a synthesizer for feedback on defect sensitivity and performance to enhance yield.

16. The method of claim 15 wherein:
the process of communicating is performed concurrently.

17. The method of claim 1 further comprising:
pre-processing circuits used for back-annotation into a behavioral binned model defects.

18. The method of claim 1 further comprising:
correlating a simulation results with observed behavior of the real system to identify defects, the correlating operation comprising:
identify a set of failing/degraded models that could cause an observed fault.

19. The method of claim 1 further comprising:
detecting anomalies within the system itself using self-simulation, the detecting operation comprising:
identify defects caused by maintenance issues; and
recommend preventative-maintenance and replacement parts.

20. A non-transitory computer-readable medium storing a set of instructions that when executed cause a computer system to perform a method of defect simulation testing and analysis for an electronic circuit or system, the method comprising:
simulating a given block of the electronic circuit or system using a plurality of test models;
segregating (characterizing) a plurality of resultant behaviors of the given block into a discrete quantity of behavior-bins that have recognizably different behaviors from each other; and
generating a behavioral-bin model by digital twinning each of the behavioral-bins.

21. The non-transitory computer-readable medium of claim 20, wherein:
the operation of digital twinning the behavioral-bin model is performed by either
i) a gradient descent least means squared (LMS) algorithm using a neural network; or
ii) manually creating a model and modifying parameters.

22. The non-transitory computer-readable medium of claim 20, wherein the method further comprises:
switching between the test models during simulation without restarting or losing results to that point in the simulation.

23. The non-transitory computer-readable medium of claim 20, wherein the method further comprises:
determining a likelihood for a given block-level behavior-bin model based on an aggregate of a likelihood for each of one or more defects occurring in the respective behavior-bin.

24. The non-transitory computer-readable medium of claim 20, wherein the method further comprises:
simulating a higher-level block behavior in the electronic circuit or system by concurrently simulating a plurality of component blocks disposed in the higher-level block.

25. The non-transitory computer-readable medium of claim 20, wherein the method further comprises:
operating more than one defect block-level behavioral-bin models concurrently to represent a given defect behavior of the block.

26. The non-transitory computer-readable medium of claim 20, wherein the method further comprises:
switching at least one block-level behavioral-bin models in a group to use a different bin in order to simulate a special defect that includes at least one of a transient defect,
an overuse of one or more components, or an aging condition.

27. A computer system comprising:
a processor for processing instructions;
an input/output device to receive input; and
a memory coupled to the processor and input/output device, the memory for storing data;
wherein the computer is configured to perform a method of defect simulation testing and analysis for an electronic circuit or system, the method comprising:
simulating a given block of the electronic circuit or system using a plurality of test models;
segregating (characterizing) a plurality of resultant behaviors of the given block into a discrete quantity of behavior-bins that have recognizably different behaviors from each other; and
generating a behavioral-bin model by digital twinning each of the behavioral-bins.
